(19) United States
(12) Patent Application Publication
(10) Pub. No.: US 2007/0045683 A1
(43) Pub. Date: Mar. 1, 2007

(54) LIGHT REFLECTIVITY CONTROLLED PHOTODIODE CELL, AND METHOD OF MANUFACTURING THE SAME

(75) Inventors: Michel Willemin, Prêles (CH); Daniel Rosenfeld, Boudry (CH)

Correspondence Address: GRIFFIN & SZIPL, PC, SUITE PH-1, 2300 NINTH STREET, SOUTH, ARLINGTON, VA, 22204, US

(73) Assignee: EM MICROELECTRONIC-MARIN S.A., Marin (CH)

(21) Appl. No.: 11/465,898

(22) Filed: Aug. 21, 2006

(30) Foreign Application Priority Data
Aug. 23, 2005 (EP) 05107734.5

(51) Int. Cl. H01L 31/113

(52) U.S. Cl. 257/292

(57) ABSTRACT

The photodiode cell (1) includes at least one photosensitive area (3), made in a silicon semiconductor substrate (2), for receiving light, particularly coherent light, and a passivation layer and a dielectric layer (4). The passivation layer is composed of at least a first silicon oxide layer (5) and a second nitride layer (6), made on the photosensitive area. The second nitride layer is made with a thickness within a determined margin, so as to be situated in a zone with the most constant possible light reflectivity independently of the thickness of the first layer. An etch (7) can be performed on one portion of the dielectric layer (4) or on the first layer (5) corresponding to half of the reception surface of the photosensitive area in order to obtain a reflectivity percentage mean of the light to be sensed by the photodiode cell.

This application claims priority from European Patent Application No. 05107734.5 filed Aug. 23, 2005, the entire disclosure of which is incorporated herein by reference.

### FIELD OF THE INVENTION

The invention concerns a light reflectivity controlled photodiode cell, particularly for coherent light. The cell can comprise either a single photodiode, or a photodiode matrix grating made in the same silicon semiconductor substrate. The photodiode cell includes at least one photosensitive area made in the substrate for receiving light and a passivation layer made on the photosensitive area. The passivation layer is composed of at least a first layer of silicon oxide and a second layer of nitride.

The invention also concerns a method of manufacturing this photodiode cell.

### BACKGROUND OF THE INVENTION

When such photodiode cells are used for sensing light, particularly coherent light from a laser, in various applications, a problem of reflectivity of the light beam on the photodiode arises. The light beam may be reflected in part on the second nitride layer of the passivation layer, and also on the first silicon oxide layer of the passivation layer. Consequently, the percentage of light sensed by the photosensitive area of the photodiode can thus be greatly reduced by interference phenomena.

In applications using only the light produced by a light emitting diode, light reflectivity on the protective layers, such as the passivation layer, is less significant. However, with this type of light emitting diode the yield defined by the optical power to electrical power ratio is better for a laser diode. Consequently, improved performance is observed for devices using light transmission by a laser diode sensed by a photodiode cell. This also reduces electrical power consumption if the device is powered by a battery or an accumulator of small size.

Another advantage of a laser diode providing coherent light is that it gives a more contrasted image than a light emitting diode. Depending upon the application, “speckles” may advantageously be used.

One of the possible applications of a laser diode and a photodiode cell made in a silicon semiconductor substrate could be a wireless computer mouse. The laser diode generates a light beam reflected onto a surface of variable roughness so as to be sensed by a photodiode cell. This photodiode cell can be a photodiode matrix grating made in the same semiconductor substrate. In this way, depending upon the intensity sensed by each photodiode, it is possible to deduce therefrom the direction of movement of the mouse or a certain speed of movement.

Since the light produced by the laser diode is coherent light, reflection onto the various protective layers of the photodiode cell intervenes, which is a drawback. The reflection percentage may be significant depending upon the thickness of the protective layers.

It is thus a main object of the invention to provide a photodiode cell made so as to monitor light reflectivity in order to overcome the aforementioned drawbacks.

### SUMMARY OF THE INVENTION

The invention therefore concerns an aforecited photodiode cell, which includes the features of at least one photosensitive well area made in a silicon semiconductor substrate for receiving a coherent light, at least one silicon oxide layer made on the photosensitive area, and at least a nitride layer on the silicon oxide layer, wherein the nitride layer has a thickness within a determined margin between two thicknesses corresponding to two successive reflectivity maximums of the nitride layer dependent on the wavelength of the coherent light to be sensed in order to obtain a layer substantially constant reflectivity percentage independently of the thickness of the silicon oxide layer.

Advantageous embodiments are defined in view of the above first embodiment. More specifically, a second embodiment of the invention concerns modifying the first embodiment of the photodiode cell so that the thickness of the nitride layer is determined so that the layer light reflectivity percentage is of the order of 25% independently of the thickness of the silicon oxide layer, and wherein the silicon oxide layer is made with at least one thickness variation on the photosensitive area. A third embodiment concerns modifying the first embodiment of the photodiode cell so that the silicon oxide layer is made with at least a first thickness over a first portion of the photosensitive area and with at least a second thickness, different from the first thickness, over a second portion of the photosensitive area. A fourth embodiment concerns modifying the third embodiment so that the silicon oxide layer is composed of at least a silicon oxide dielectric layer made on the photosensitive area and a first silicon oxide layer on the dielectric layer, the first layer constituting with the second nitride layer a passivation layer, and wherein the dielectric layer or the first layer of the passivation layer is realized with at least a first thickness over a first portion of the photosensitive area and with at least a second thickness, different from the first thickness, over a second portion of the photosensitive area. A fifth embodiment concerns modifying the fourth embodiment so that the difference in thickness of the dielectric layer or of the first layer over the two portions of the photosensitive area is determined on the basis of the difference in thickness between a thickness of the dielectric layer or the first silicon oxide layer corresponding to a minimum light reflectivity percentage and a thickness of the dielectric layer or the first silicon oxide layer corresponding to a maximum light reflectivity percentage.

A sixth embodiment of the invention concerns modifying the photodiode cell of the third embodiment so that the dimension of the first light reception portion of the photosensitive area is substantially equal to the dimension of the second light reception portion of the photosensitive area. A seventh embodiment of the invention concerns modifying the photodiode cell of the third embodiment so that several first portions of the silicon oxide layer have a first thickness, wherein several second portions of the silicon oxide layer have a second thickness, so as to be distributed over the photosensitive area in a mosaic form, and wherein the dimension of all of the first portions is substantially equal to the dimension of all of the second portions. An eighth embodiment of the invention concerns modifying the photodiode cell of the first embodiment so that the silicon oxide layer is composed of at least a silicon oxide dielectric layer made on the photosensitive area and a first silicon oxide layer on the dielectric layer, the first layer constituting with the second nitride layer a passivation layer, and wherein the dielectric layer is realized with a variable thickness on the photosensitive area, the thickness of the oxide layer being maximum in proximity to the edge of the photosensitive area and minimum in proximity to the center of the photosensitive area. A ninth embodiment of the invention concerns modifying the photodiode cell the first embodiment so that it is capable of sensing coherent light from a laser source with a wavelength close to 850 nm, wherein the nitride layer has a thickness of a value close to M times 210 nm, where M is an integer number higher than or equal to 1.

One advantage of the photodiode cell according to the invention lies in the fact that by controlling the thickness of the second nitride layer of the passivation layer, it is possible to obtain substantially constant reflectivity or a constant reflectivity percentage. This constant reflectivity percentage is independent of the thickness of the first silicon oxide layer of the passivation layer, and the thickness of a dielectric layer between the photosensitive area and the first layer. The constant reflection percentage can be a value close to 25%, which is much lower than maximum reflectivity, which can be of the order of 50%.

The thickness of the nitride layer has to be controlled as a function of the manufacturing method used and the wavelength of the light to be sensed. The thickness is checked during the photodiode cell manufacturing process for each wafer of photodiode cells and for each batch of wafers.

Advantageously, the dielectric layer or the first layer of the passivation layer is etched to a first thickness over at least one portion of the photosensitive area. The dielectric layer or the first layer has a second thickness, different from the first thickness over a second portion of the photosensitive layer. The difference in thickness of the dielectric layer or the first layer over the two portions of the photosensitive area is determined as a function of the difference in thickness of the first silicon oxide layer between a minimum and maximum light reflectivity percentage.

The dimension of the first portion of the photosensitive area can be equal to the dimension of the second portion of the photosensitive layer. Several first portions and several second portions may advantageously be distributed in a mosaic above the photosensitive area, for example in the form of a checkerboard. In this manner, a mean light reflectivity percentage can be obtained for the first oxide layer and the dielectric layer, whose thickness cannot be controlled.

The invention therefore also concerns a method of manufacturing an aforecited photodiode cell, which includes the features defined in a tenth embodiment, which a method of manufacturing of at least one photodiode cell according to the first embodiment, for which at: least a silicon oxide layer is realized on a photosensitive well area of the silicon semiconductor substrate, able to sense light, and a nitride layer realized on the silicon oxide layer, wherein the nitride layer is realized with a thickness within a determined margin between two thicknesses corresponding to two successive reflectivity maximums of the nitride layer dependent on the wavelength of the coherent light to be sensed in order to obtain a layer substantially constant reflectivity percentage independently of the thickness of the silicon oxide layer.

Particular steps of the method are defined in view of the tenth embodiment. More specifically, an eleventh embodiment of the invention concerns modifying the manufacturing method of the tenth embodiment so that the nitride layer is realized with a thickness so that the layer light reflectivity percentage is of the order of 25% independently of the thickness of the silicon oxide layer realized on the photosensitive area, and wherein the silicon oxide layer is made with at least one thickness variation on the photosensitive area. A twelfth embodiment of the invention concerns modifying the manufacturing method of the tenth embodiment so that the silicon oxide layer is made with at least a first thickness over a first portion of the photosensitive area and with at least a second thickness, different from the first thickness, over a second portion of the photosensitive area. A thirteenth embodiment of the invention concerns modifying the manufacturing method of the twelfth embodiment so that the difference in thickness of the silicon oxide layer is obtained by etching of a portion of the silicon oxide layer or by additional deposition of the silicon oxide layer. A fourteenth embodiment of the invention concerns modifying the manufacturing method of the twelfth embodiment so that a silicon oxide dielectric layer being part of the silicon oxide layer is realized above the photosensitive area before realizing a first silicon oxide layer on the dielectric layer, wherein the dielectric layer or the first silicon oxide layer is chemically etched over at least a first portion of the photosensitive area so that the difference in thickness between the etched layer above the first portion and the dielectric layer or the first layer above a second portion of the photosensitive area is determined on the basis of the difference in thickness between a thickness of the dielectric layer or the first silicon oxide layer corresponding to a minimum light reflectivity percentage and a thickness of the dielectric layer or the first silicon oxide layer corresponding to a maximum light reflectivity percentage, and wherein the dimension of the first light reception portion of the photosensitive area is substantially equal to the dimension of the second light reception portion of the photosensitive area. A fifteenth embodiment concerns modifying the manufacturing method of the tenth embodiment so that the silicon oxide layer is realized with a variable thickness obtained by gradual chemical etching to have a maximum thickness in proximity to the edge of the photosensitive area and a minimum thickness in proximity to the centre of the photosensitive area.

### BRIEF DESCRIPTION OF THE DRAWINGS

The objects, advantages and features of the photodiode cell and the method of manufacturing of the same will appear more clearly in the following description with reference to the drawings, in which:

FIG. 1 shows in a simplified manner a vertical cross-section of a photodiode cell sensing a part of a light beam, the other part of which is reflected onto the layers of the passivation layer and the dielectric layer,

FIG. 2 shows a reflectivity graph as a function of the thickness of the first oxide layer of the passivation layer relative to the thickness of the second nitride layer of the passivation layer,

FIG. 3 shows in a simplified manner a vertical cross-section of a photodiode cell wherein only the passivation layer is made above the photosensitive area of the semiconductor substrate,

FIGS. 4a and 4b show in a simplified manner a vertical cross-section of the photodiode cell with two thicknesses of the dielectric layer over the first and second portions of the photosensitive area according to the invention, and a top view of the cell showing the two portions on the photosensitive area,

FIG. 5 shows in a simplified manner a top view of the photodiode cell with several first portions of the dielectric layer of different thickness from several second portions on the photosensitive layer, and

FIG. 6 shows in a simplified manner a vertical cross-section of the photodiode cell wherein the dielectric layer is gradually etched over the photosensitive area.

### DETAILED DESCRIPTION OF THE INVENTION

In the following description, since various steps of the method of manufacturing these photodiode cells are well known, they will not be explained in detail. Reference will mainly be made only to the structure of a photodiode cell for controlling the reflectivity of light to be sensed. For the sake of simplification, the cell comprises a single photodiode, even if generally it would comprise a photodiode matrix grating. The light sensed by the cell could be coherent light produced by a laser diode that is not shown.

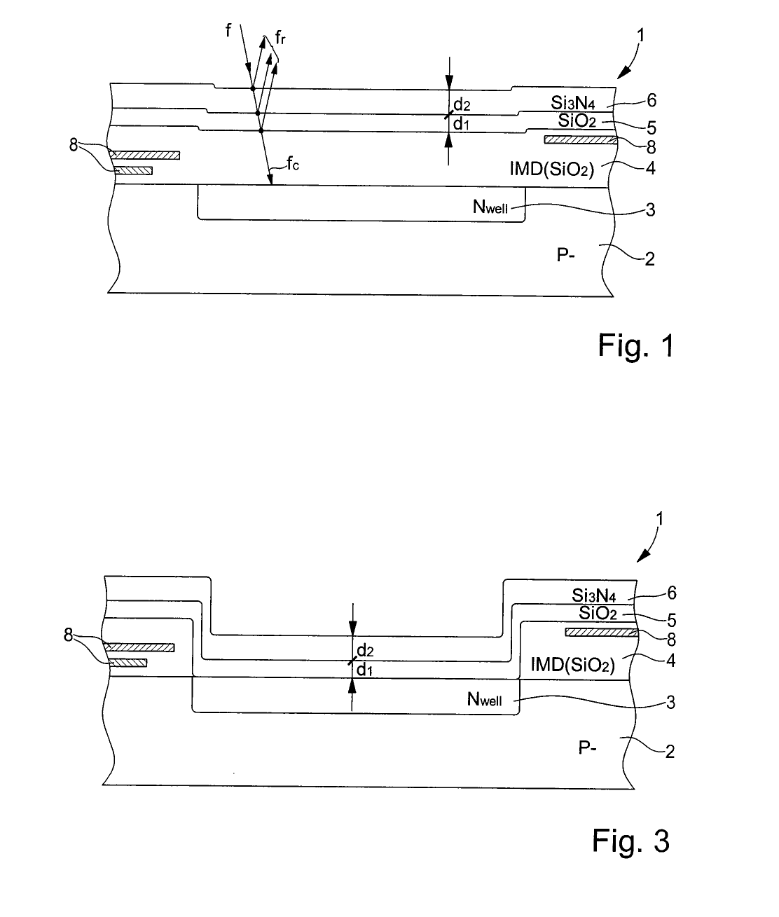

FIG. 1 shows a partial cross-section of a photodiode cell 1 composed of a single photodiode. This photodiode cell 1 is made in a semiconductor silicon substrate 2. During the manufacturing method, several photodiode cells can be made on the same wafer, but only one photodiode cell is explained hereinafter.

Photodiode cell 1 includes a photosensitive area 3, such as an n-well area, of N type conductivity, which is made in a silicon semiconductor substrate 2 of P-type conductivity. The photosensitive area is able to sense one part of a light beam f, for example a coherent light beam provided by a diode laser that is not shown.

An inter metal dielectric (IMD) layer of silicon oxide 4 is made at the surface of photosensitive area 3 and portions of substrate 2 surrounding the photosensitive area. The thickness of this transparent layer is almost impossible to control, since it also depends upon the number of metallising layers 8 used during the cell manufacturing process. This manufacturing process may be a TSMC type process at 0.5 μm or 0.18 μm. A certain dielectric layer thickness is thus achieved between each metallising level. The total dielectric layer thickness can be of the order of 5 μm.

In order to protect the elements of the photodiode cell, a passivation layer is deposited at the end of the manufacturing process steps above dielectric layer 4. This passivation layer is composed in particular of a first silicon oxide layer SiO₂ 5 of thickness d1 just above dielectric layer 4, and a second nitride layer Si₃N₄ 6 of thickness d2 above the first layer.

When a coherent light beam f has to be sensed by photosensitive area 3 of photodiode cell 1, one part fᵣ of the beam is reflected onto the second nitride layer 6, onto silicon oxide layer 5 and possibly onto dielectric layer 4. This reflection is partly due also to the different refraction indices of the protective layers. Thus, only a certain percentage f_{c} of light beam f is sensed by photosensitive area 3.

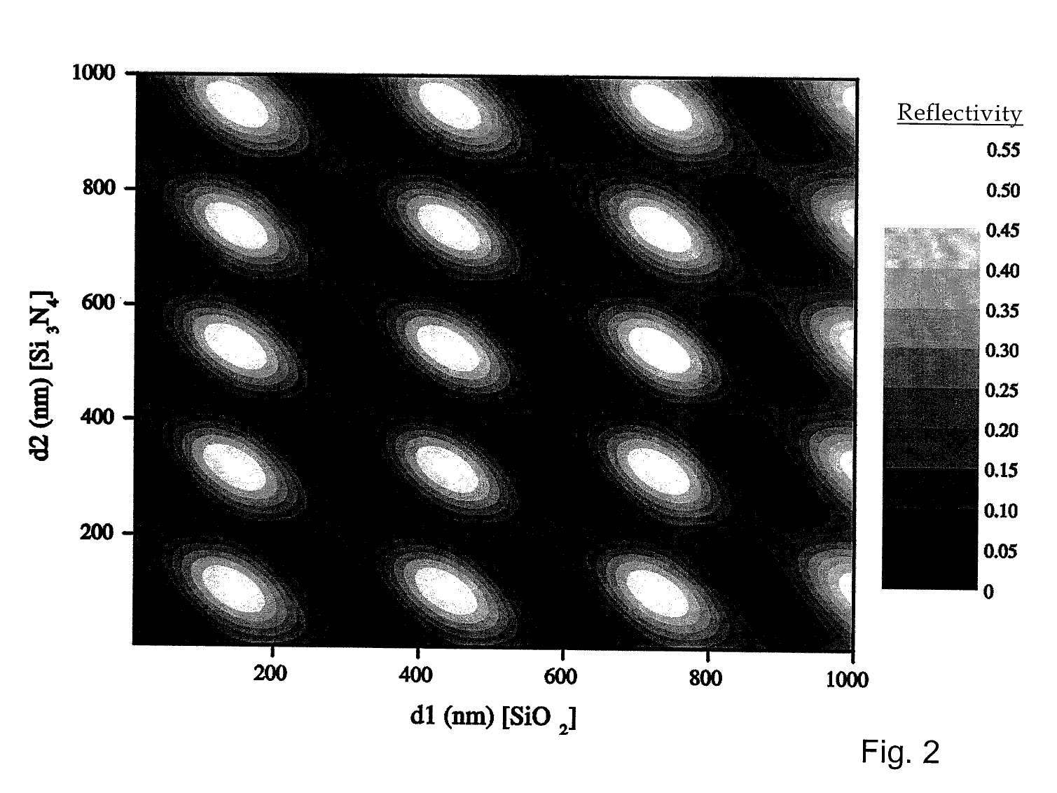

In FIG. 2, a graph shows the light reflectivity of the photodiode cell as a function of the thickness d1 of the first silicon oxide layer in relation to thickness d2 of the second nitride layer. It will be noted in FIG. 2 that, by controlling the thickness d2 of the second nitride layer in a determined margin between two reflectivity maximums, it is possible to obtain substantially constant reflectivity. This constant reflectivity is independent of the thickness of the first oxide layer and also independent of the thickness of the dielectric layer.

The thickness of this second nitride layer must be checked during the manufacturing process for each photodiode cell wafer, and also for each batch of wafers, since certain differences between wafers or between batches might be observed during the same manufacturing process. For a coherent light wavelength of the order of 850 nm, the thickness d2 of the second nitride layer can have a value M times 210 nm, where M is an integer number higher than or equal to 1. By controlling this nitride layer in accordance with the invention, it is possible to obtain a photodiode cell whose light reflectivity percentage is close to 25% in relation to a maximum, which can be of the order of 50% for example, independently of the thickness of the silicon oxide layer. This means a reflectivity of 0.25 in relation to a maximum of 0.5 on a scale from 0 to 1, as shown in FIG. 2. As the reflectivity is well controlled, it facilitates calibration and qualification steps of photodiode cells.

If the dielectric layer can be entirely eliminated from the surface of the photosensitive area as shown in FIG. 3, one could also envisage controlling the thickness d1 of the first silicon oxide layer. By choosing a thickness d2 for the second nitride layer as indicated hereinbefore, it is possible to lower the reflectivity percentage between 25% and 20% by also controlling the thickness d1 of the first layer.

Of course, if it were possible to remove the dielectric layer before depositing the passivation layer, it would be possible to make a photodiode cell whose reflectivity percentage would be close to 0%. In order to do this with a light wavelength of the order of 850 nm, the thickness d1 of the first silicon oxide layer could be controlled to a value of N times 290 nm, where N is an integer number higher than or equal to 1. In such case, the thickness d2 of the nitride layer would have to be for example of the order of 105 nm, 315 nm, 525 nm or 735 nm.

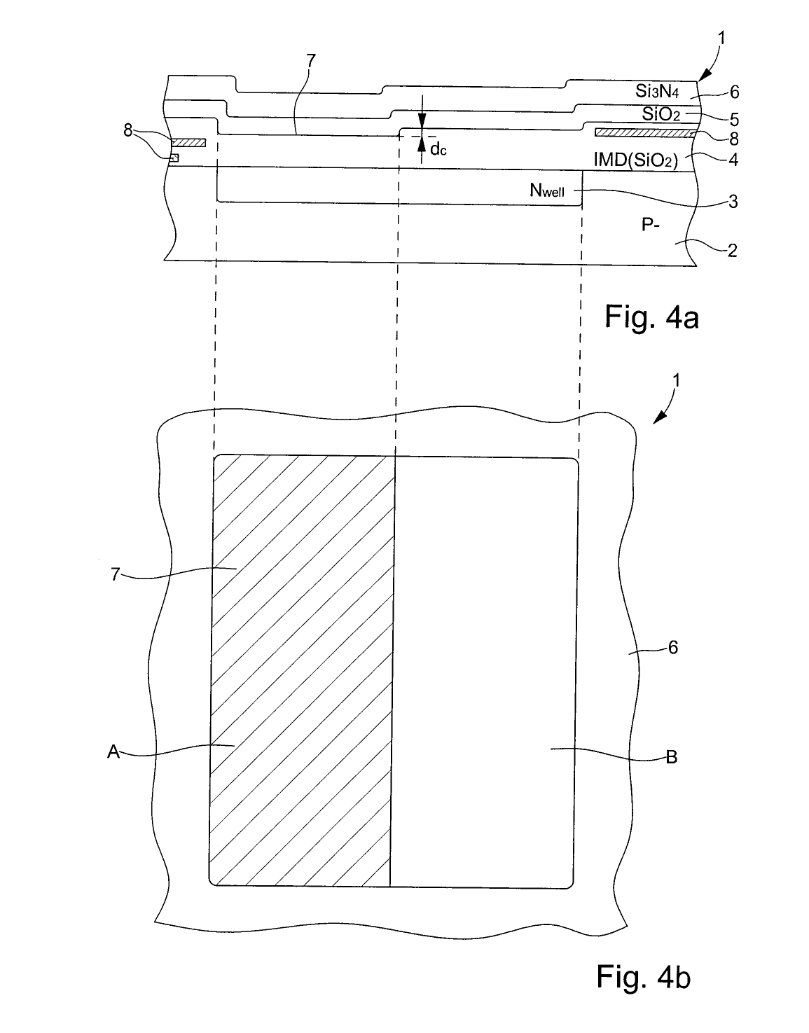

In addition to controlling the thickness d2 of the nitride layer, a chemical etch 7 can also be made to a first thickness of one portion A of the dielectric layer 4 on the photosensitive area as shown in FIGS. 4a and 4b. Thus, a difference in thickness d_{c} is realised between the dielectric layer 4 etched on portion A and the non-etched dielectric layer on a portion B at a second thickness on the photosensitive area. This difference in thickness is determined as a function of the difference in thickness of first silicon oxide layer 5 between a minimum and maximum light reflectivity percentage. For a light wavelength of the order of 850 nm, this difference in thickness d_{c} may be of the order of 145 nm.

The dimension of portions A and B approximately corresponds to the reception surface of photosensitive area 3. The reception surface can be 28 μm by 28 μm. Preferably the dimension of first light reception portion A of photosensitive area 3 is substantially equal to the dimension of second light reception portion B of the photosensitive area. In this manner, independently of the fluctuations in thickness in the dielectric layer and the silicon oxide layer, a light reflectivity percentage mean can be obtained for the two portions. One of the two light reception portions A and B of photosensitive area 3 is thus more sensitive than the other portion.

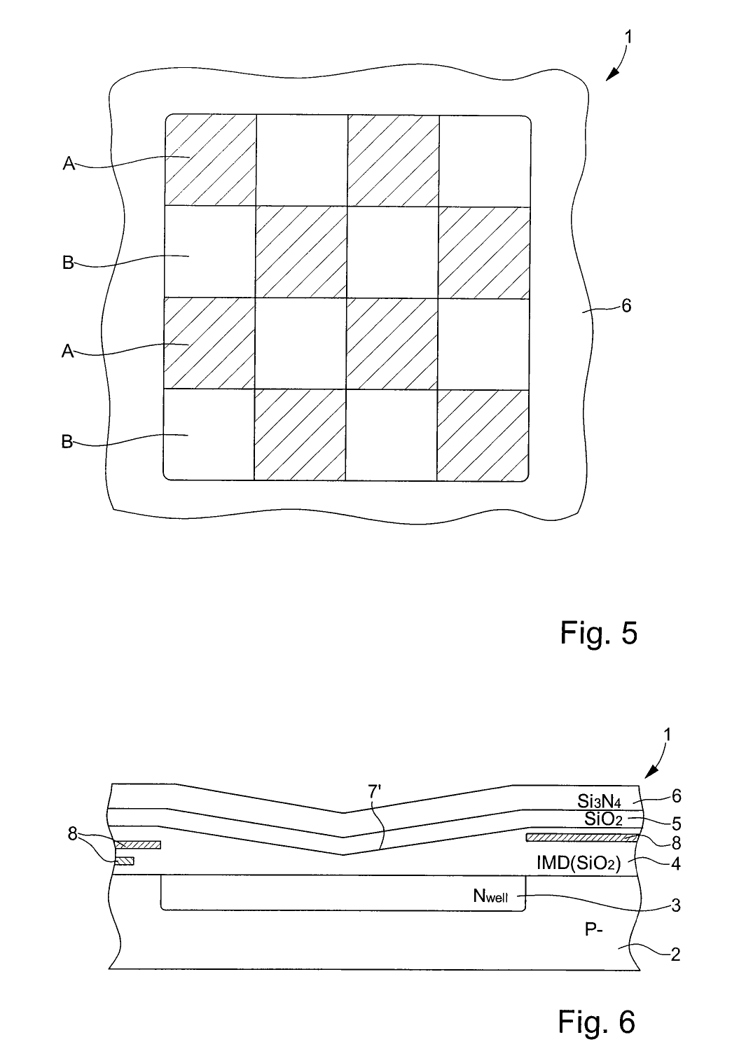

As shown in a simplified manner in FIG. 5, several dielectric layer portions A at a first thickness, and several dielectric portions B at a second thickness may be provided. These first and second portions A and B are distributed alternately on the photosensitive area in the form of a mosaic. The mosaic can form a checkerboard, but also an arrangement of triangular shaped portions seen from above. With this distribution of the first and second layer portions of different thickness, a better mean light reflectivity percentage can be obtained.

It should be noted that it is also possible to etch the first silicon oxide layer instead of etching the dielectric layer to obtain layers of different thickness. Moreover, instead of an etching operation, an additional deposition of dielectric layer 4 or the first layer on at least one portion of the photosensitive layer could be envisaged.

FIG. 6 shows a cross-section of another embodiment of photodiode cell 1. Dielectric layer 4 may be etched by gradual chemical etching above the reception surface of photosensitive area 3. The etched dielectric layer 4 has a variable thickness over photosensitive area 3. The thickness may be maximum in proximity to the edge of the photosensitive area and minimum in proximity to the centre of the photosensitive area.

Of course, instead of etching the dielectric layer, one could also envisage etching the first silicon oxide layer of the passivation layer.

It should also be noted that the conductivity of the semiconductor substrate of the photodiode cell might also be of the N− type in which a P-well is made to act as the photosensitive area. However, the N+ photosensitive area could also be made in the P-well area. Other possibilities can also be envisaged.

From the description that has just been given, multiple variants of the photodiode cell and the method of manufacturing the cell can be devised by those skilled in the art without departing from the scope of the invention defined by the claims. The passivation layer may also include a SiON layer.

This application claims priority from European Patent Application No. 05107734.5 filed Aug. 23, 2005, the entire disclosure of which is incorporated herein by reference The invention concerns a light reflectivity controlled photodiode cell, particularly for coherent light. The cell can comprise either a single photodiode, or a photodiode matrix grating made in the same silicon semiconductor substrate. The photodiode cell includes at least one photosensitive area made in the substrate for receiving light and a passivation layer made on the photosensitive area. The passivation layer is composed of at least a first layer of silicon oxide and a second layer of nitride.

The invention also concerns a method of manufacturing this photodiode cell.

When such photodiode cells are used for sensing light, particularly coherent light from a laser, in various applications, a problem of reflectivity of the light beam on the photodiode arises. The light beam may be reflected in part on the second nitride layer of the passivation layer, and also on the first silicon oxide layer of said passivation layer. Consequently, the percentage of light sensed by the photosensitive area of the photodiode can thus be greatly reduced by interference phenomena.

In applications using only the light produced by a light emitting diode, light reflectivity on the protective layers, such as the passivation layer, is less significant. However, with this type of light emitting diode the yield defined by the optical power to electrical power ratio is better for a laser diode. Consequently, improved performance is observed for devices using light transmission by a laser diode sensed by a photodiode cell. This also reduces electrical power consumption if the device is powered by a battery or an accumulator of small size.

Another advantage of a laser diode providing coherent light is that it gives a more contrasted image than a light emitting diode. Depending upon the application, “speckles” may advantageously be used.

One of the possible applications of a laser diode and a photodiode cell made in a silicon semiconductor substrate could be a wireless computer mouse. The laser diode generates a light beam reflected onto a surface of variable roughness so as to be sensed by a photodiode cell. This photodiode cell can be a photodiode matrix grating made in the same semiconductor substrate. In this way, depending upon the intensity sensed by each photodiode, it is possible to deduce therefrom the direction of movement of the mouse or a certain speed of movement.

Since the light produced by the laser diode is coherent light, reflection onto the various protective layers of the photodiode cell intervenes, which is a drawback. The reflection percentage may be significant depending upon the thickness of the protective layers.

It is thus a main object of the invention to provide a photodiode cell made so as to monitor light reflectivity in order to overcome the aforementioned drawbacks.

The invention therefore concerns an aforecited photodiode cell, which includes the features mentioned in claim 1.

Advantageous embodiments are defined in the dependent claims 2 to 9.

One advantage of the photodiode cell according to the invention lies in the fact that by controlling the thickness of the second nitride layer of the passivation layer, it is possible to obtain substantially constant reflectivity or a constant reflectivity percentage. This constant reflectivity percentage is independent of the thickness of the first silicon oxide layer of the passivation layer, and the thickness of a dielectric layer between the photosensitive area and the first layer. The constant reflection percentage can be a value close to 25%, which is much lower than maximum reflectivity, which can be of the order of 50%.

The thickness of the nitride layer has to be controlled as a function of the manufacturing method used and the wavelength of the light to be sensed. The thickness is checked during the photodiode cell manufacturing process for each wafer of photodiode cells and for each batch of wafers.

Advantageously, the dielectric layer or the first layer of the passivation layer is etched to a first thickness over at least one portion of the photosensitive area. The dielectric layer or the first layer has a second thickness, different from the first thickness over a second portion of the photosensitive layer. The difference in thickness of the dielectric layer or the first layer over the two portions of the photosensitive area is determined as a function of the difference in thickness of the first silicon oxide layer between a minimum and maximum light reflectivity percentage.

The dimension of the first portion of the photosensitive area can be equal to the dimension of the second portion of the photosensitive layer. Several first portions and several second portions may advantageously be distributed in a mosaic above the photosensitive area, for example in the form of a checkerboard. In this manner, a mean light reflectivity percentage can be obtained for the first oxide layer and the dielectric layer, whose thickness cannot be controlled.

The invention therefore also concerns a method of manufacturing an aforecited photodiode cell, which includes the features defined in claim 10.

Particular steps of the method are defined in dependent claims 11 to 15.

The objects, advantages and features of the photodiode cell and the method of manufacturing of the same will appear more clearly in the following description with reference to the drawings, in which:

FIG. 1 shows in a simplified manner a vertical cross-section of a photodiode cell sensing a part of a light beam, the other part of which is reflected onto the layers of the passivation layer and the dielectric layer,

FIG. 2 shows a reflectivity graph as a function of the thickness of the first oxide layer of the passivation layer relative to the thickness of the second nitride layer of the passivation layer,

FIG. 3 shows in a simplified manner a vertical cross-section of a photodiode cell wherein only the passivation layer is made above the photosensitive area of the semiconductor substrate,

FIGS. 4a and 4b show in a simplified manner a vertical cross-section of the photodiode cell with two thicknesses of the dielectric layer over the first and second portions of the photosensitive area according to the invention, and a top view of the cell showing the two portions on the photosensitive area,

FIG. 5 shows in a simplified manner a top view of the photodiode cell with several first portions of the dielectric layer of different thickness from several second portions on the photosensitive layer, and

FIG. 6 shows in a simplified manner a vertical cross-section of the photodiode cell wherein the dielectric layer is gradually etched over the photosensitive area.

In the following description, since various steps of the method of manufacturing these photodiode cells are well known, they will not be explained in detail. Reference will mainly be made only to the structure of a photodiode cell for controlling the reflectivity of light to be sensed. For the sake of simplification, the cell comprises a single photodiode, even if generally it would comprise a photodiode matrix grating. The light sensed by the cell could be coherent light produced by a laser diode that is not shown.

FIG. 1 shows a partial cross-section of a photodiode cell 1 composed of a single photodiode. This photodiode cell 1 is made in a semiconductor silicon substrate 2. During the manufacturing method, several photodiode cells can be made on the same wafer, but only one photodiode cell is explained hereinafter.

Photodiode cell 1 includes a photosensitive area 3, such as an n-well area, of N type conductivity, which is made in a silicon semiconductor substrate 2 of P- type conductivity. The photosensitive area is able to sense one part of a light beam f, for example a coherent light beam provided by a diode laser that is not shown.

An inter metal dielectric (IMD) layer of silicon oxide 4 is made at the surface of photosensitive area 3 and portions of substrate 2 surrounding the photosensitive area. The thickness of this transparent layer is almost impossible to control, since it also depends upon the number of metallising layers 8 used during the cell manufacturing process. This manufacturing process may be a TSMC type process at 0.5 μm or 0.18 μm. A certain dielectric layer thickness is thus achieved between each metallising level. The total dielectric layer thickness can be of the order of 5 μm.

In order to protect the elements of the photodiode cell, a passivation layer is deposited at the end of the manufacturing process steps above dielectric layer 4. This passivation layer is composed in particular of a first silicon oxide layer SiO₂ 5 of thickness d1 just above dielectric layer 4, and a second nitride layer Si₃N₄ 6 of thickness d2 above the first layer.

When a coherent light beam f has to be sensed by photosensitive area 3 of photodiode cell 1, one part fᵣ of the beam is reflected onto the second nitride layer 6, onto silicon oxide layer 5 and possibly onto dielectric layer 4. This reflection is partly due also to the different refraction indices of the protective layers. Thus, only a certain percentage f_{c} of light beam f is sensed by photosensitive area 3.

In FIG. 2, a graph shows the light reflectivity of the photodiode cell as a function of the thickness d1 of the first silicon oxide layer in relation to thickness d2 of the second nitride layer. It will be noted in FIG. 2 that, by controlling the thickness d2 of the second nitride layer in a determined margin between two reflectivity maximums, it is possible to obtain substantially constant reflectivity. This constant reflectivity is independent of the thickness of the first oxide layer and also independent of the thickness of the dielectric layer.

The thickness of this second nitride layer must be checked during the manufacturing process for each photodiode cell wafer, and also for each batch of wafers, since certain differences between wafers or between batches might be observed during the same manufacturing process. For a coherent light wavelength of the order of 850 nm, the thickness d2 of the second nitride layer can have a value M times 210 nm, where M is an integer number higher than or equal to 1. By controlling this nitride layer in accordance with the invention, it is possible to obtain a photodiode cell whose light reflectivity percentage is close to 25% in relation to a maximum, which can be of the order of 50% for example, independently of the thickness of the silicon oxide layer. This means a reflectivity of 0.25 in relation to a maximum of 0.5 on a scale from 0 to 1, as shown in FIG. 2. As the reflectivity is well controlled, it facilitates calibration and qualification steps of photodiode cells.

If the dielectric layer can be entirely eliminated from the surface of the photosensitive area as shown in FIG. 3, one could also envisage controlling the thickness d1 of the first silicon oxide layer. By choosing a thickness d2 for the second nitride layer as indicated hereinbefore, it is possible to lower the reflectivity percentage between 25% and 20% by also controlling the thickness d1 of the first layer.

Of course, if it were possible to remove the dielectric layer before depositing the passivation layer, it would be possible to make a photodiode cell whose reflectivity percentage would be close to 0%. In order to do this with a light wavelength of the order of 850 nm, the thickness d1 of the first silicon oxide layer could be controlled to a value of N times 290 nm, where N is an integer number higher than or equal to 1. In such case, the thickness d2 of the nitride layer would have to be for example of the order of 105 nm, 315 nm, 525 nm or 735 nm.

In addition to controlling the thickness d2 of the nitride layer, a chemical etch 7 can also be made to a first thickness of one portion A of the dielectric layer 4 on the photosensitive area as shown in FIGS. 4a and 4b. Thus, a difference in thickness d_{c} is realised between the dielectric layer 4 etched on portion A and the non-etched dielectric layer on a portion B at a second thickness on the photosensitive area. This difference in thickness is determined as a function of the difference in thickness of first silicon oxide layer 5 between a minimum and maximum light reflectivity percentage. For a light wavelength of the order of 850 nm, this difference in thickness d_{c} may be of the order of 145 nm.

The dimension of portions A and B approximately corresponds to the reception surface of photosensitive area 3. The reception surface can be 28 μm by 28 μm. Preferably the dimension of first light reception portion A of photosensitive area 3 is substantially equal to the dimension of second light reception portion B of the photosensitive area. In this manner, independently of the fluctuations in thickness in the dielectric layer and the silicon oxide layer, a light reflectivity percentage mean can be obtained for the two portions. One of the two light reception portions A and B of photosensitive area 3 is thus more sensitive than the other portion.

As shown in a simplified manner in FIG. 5, several dielectric layer portions A at a first thickness, and several dielectric portions B at a second thickness may be provided. These first and second portions A and B are distributed alternately on the photosensitive area in the form of a mosaic. The mosaic can form a checkerboard, but also an arrangement of triangular shaped portions seen from above. With this distribution of the first and second layer portions of different thickness, a better mean light reflectivity percentage can be obtained.

It should be noted that it is also possible to etch the first silicon oxide layer instead of etching the dielectric layer to obtain layers of different thickness. Moreover, instead of an etching operation, an additional deposition of dielectric layer 4 or the first layer on at least one portion of the photosensitive layer could be envisaged.

FIG. 6 shows a cross-section of another embodiment of photodiode cell 1. Dielectric layer 4 may be etched by gradual chemical etching above the reception surface of photosensitive area 3. The etched dielectric layer 4 has a variable thickness over photosensitive area 3. The thickness may be maximum in proximity to the edge of the photosensitive area and minimum in proximity to the centre of the photosensitive area.

Of course, instead of etching the dielectric layer, one could also envisage etching the first silicon oxide layer of the passivation layer.

It should also be noted that the conductivity of the semiconductor substrate of the photodiode cell might also be of the N− type in which a P-well is made to act as the photosensitive area. However, the N+ photosensitive area could also be made in the P-well area. Other possibilities can also be envisaged.

From the description that has just been given, multiple variants of the photodiode cell and the method of manufacturing said cell can be devised by those skilled in the art without departing from the scope of the invention defined by the claims. The passivation layer may also include a SiON layer.

1. A photodiode cell including:
at least one photosensitive well area made in a silicon semiconductor substrate for receiving a coherent light;
at least one silicon oxide layer made on the photosensitive area; and
at least a nitride layer on the silicon oxide layer, wherein the nitride layer has a thickness within a determined margin between two thicknesses corresponding to two successive reflectivity maximums of the nitride layer dependent on wavelength of the coherent light to be received in order to obtain a layer of substantially constant reflectivity percentage independently of thickness of the silicon oxide layer.

2. The photodiode cell according to claim 1, wherein the thickness of the nitride layer is determined so that the layer light reflectivity percentage is of the order of 25% independently of the thickness of the silicon oxide layer, and wherein the silicon oxide layer is made with at least one thickness variation on the photosensitive area.

3. The photodiode cell according to claim 1, wherein the silicon oxide layer is made with at least a first thickness over a first light reception portion of the photosensitive area and with at least a second thickness, different from the first thickness, over a second light reception portion of the photosensitive area.

4. The photodiode cell according to claim 3, wherein the silicon oxide layer comprises at least a silicon oxide dielectric layer made on the photosensitive area and a first silicon oxide layer on the dielectric layer, said first layer constituting with the second nitride layer a passivation layer, and wherein the dielectric layer or the first layer of the passivation layer is formed with at least a third thickness over a third portion of the photosensitive area and with at least a fourth thickness, different from the third thickness, over a fourth portion of the photosensitive area.

5. The photodiode cell according to claim 4, wherein the difference in thickness of the dielectric layer or of the first layer over the two portions of the photosensitive area is determined on the basis of a difference in thickness between a thickness of the dielectric layer or the first silicon oxide layer corresponding to a minimum light reflectivity percentage and a thickness of the dielectric layer or the first silicon oxide layer corresponding to a maximum light reflectivity percentage.

6. The photodiode cell according to claim 3, wherein a dimension of the first light reception portion of the photosensitive area is substantially equal to ate dimension of the second light reception portion of the photosensitive area.

7. The photodiode cell according to claim 3, wherein several first portions of the silicon oxide layer have the first thickness, wherein several second portions of the silicon oxide layer have the second thickness, so as to be distributed over the photosensitive area in a mosaic form, and wherein a dimension of all of the first portions is substantially equal to a dimension of all of the second portions.

8. The photodiode cell according to claim 1, wherein the silicon oxide layer comprises at least a silicon oxide dielectric layer made on the photosensitive area and a first silicon oxide layer on the dielectric layer, said first layer constituting with the second nitride layer a passivation layer, and wherein the dielectric layer is formed with a variable thickness on the photosensitive area, the thickness of said oxide layer being maximum in proximity to an edge of the photosensitive area and minimum in proximity to a center of the photosensitive area.

9. The photodiode cell according to claim 1, wherein the nitride layer has a thickness of a value close to M times 210 nm, where M is an integer number higher than or equal to 1, so that the photodiode cell is capable of sensing coherent light from a laser source with a wavelength close to 850 nm.

10. A method of manufacturing of at least one photodiode cell according to claim 1, comprising the steps of:
forming at least a silicon oxide layer on the photosensitive well area of the silicon semiconductor substrate, able to sense light; and
forming a nitride layer realized on the silicon oxide layer, wherein the nitride layer is formed with a thickness within a determined margin between two thicknesses corresponding to two successive reflectivity maximums of the nitride layer dependent on the wavelength of the coherent light to be received in order to obtain the layer of substantially constant reflectivity percentage independently of thickness of the silicon oxide layer.

11. The manufacturing method according to claim 10, wherein the nitride layer is formed with a thickness so that the layer light reflectivity percentage is of the order of 25% independently of thickness of the silicon oxide layer formed on the photosensitive area, and wherein the silicon oxide layer is made with at least one thickness variation on the photosensitive area.

12. The manufacturing method according to claim 10, wherein the silicon oxide layer is made with at least a first thickness over a first light reception portion of the photosensitive area and with at least a second thickness, different from the first thickness, over a second light reception portion of the photosensitive area.

13. The manufacturing method according to claim 12, wherein the difference in thickness between the first thickness and the second thickness of the silicon oxide layer is obtained by etching a portion of the silicon oxide layer or by additional deposition of the silicon oxide layer.

14. The manufacturing method according to claim 12, wherein a silicon oxide dielectric layer that is part of the silicon oxide layer is formed above the photosensitive area before formed a first silicon oxide layer on the dielectric layer, wherein the dielectric layer or the first silicon oxide layer is chemically etched over at least a third portion of the photosensitive area so that the difference in thickness between the etched layer above the third portion and the dielectric layer or the first layer above a third portion of the photosensitive area is determined on the basis of the difference in thickness between a thickness of the dielectric layer or the first silicon oxide layer corresponding to a minimum light reflectivity percentage and a thickness of the dielectric layer or the first silicon oxide layer corresponding to a maximum light reflectivity percentage, and wherein a dimension of the first light reception portion of the photosensitive area is substantially equal to a dimension of the second light reception portion of the photosensitive area.

15. The manufacturing method according to claim 10, wherein the silicon oxide layer is formed with a variable thickness obtained by gradual chemical etching to have a maximum thickness in proximity to an edge of the photosensitive area and a minimum thickness in proximity to a center of the photosensitive area.
